(19) United States
(12) Patent Application Publication
(10) Pub. No.: US 2024/0030106 A1
(43) Pub. Date: Jan. 25, 2024

(54) SEMICONDUCTOR DEVICE

(71) Applicant: ROHM CO., LTD., Kyoto-shi (JP)

(72) Inventors: Yosui FUTAMURA, Kyoto-shi (JP); Shunya MIKAMI, Kyoto-shi (JP)

(21) Appl. No.: 18/480,978

(22) Filed: Oct. 4, 2023

Related U.S. Application Data
(63) Continuation of application No. PCT/JP2022/012285, filed on Mar. 17, 2022.

(30) Foreign Application Priority Data
Apr. 12, 2021 (JP) 2021-067284

(51) Int. Cl. H01L 23/495; H01L 23/00

(52) U.S. Cl. CPC H01L 23/49513; H01L 24/05; H01L 24/08; H01L 24/09; H01L 24/45; H01L 24/48; H01L 24/32; H01L 2224/05073; H01L 2224/05573; H01L 2224/05578; H01L 2224/05686; H01L 2224/08059; H01L 2224/09055; H01L 2224/32245; H01L 2224/45124; H01L 2224/45147; H01L 2224/48245; H01L 2924/182; H01L 2924/186

(57) ABSTRACT

A semiconductor device includes a semiconductor element, a sealing resin and a covering portion. The semiconductor element includes an element body containing a semiconductor, and a first electrode disposed on the element body. The sealing resin covers the semiconductor element. The covering portion is interposed between the first electrode and the sealing resin. The covering portion contains a material having a higher thermal conductivity than the sealing resin. The first electrode of the semiconductor element includes a groove portion held in contact with the covering portion.

### TECHNICAL FIELD

The present disclosure relates to a semiconductor device.

### BACKGROUND ART

Switching elements are used to control an electric current in various industrial instruments and automobiles. JP-A-2019-212930 discloses an example of conventional switching elements. In switching elements, energy is produced by an electromotive force generated when an electric current is blocked. The switching elements absorb this energy through a function known as active clamping.

### BRIEF DESCRIPTION OF THE DRAWINGS

FIG. 1 is a plan view showing a semiconductor device according to a first embodiment of the present disclosure.

FIG. 2 is a plan view showing relevant portions of the semiconductor device according to the first embodiment of the present disclosure.

FIG. 3 is a plan view showing relevant portions of the semiconductor device according to the first embodiment of the present disclosure.

FIG. 4 is a front view showing the semiconductor device according to the first embodiment of the present disclosure.

FIG. 5 is a side view showing the semiconductor device according to the first embodiment of the present disclosure.

FIG. 6 is a cross-sectional view taken along line VI-VI in FIG. 3.

FIG. 7 is a cross-sectional view taken along line VII-VII in FIG. 3.

FIG. 8 is an enlarged cross-sectional view showing relevant portions of the semiconductor device according to the first embodiment of the present disclosure.

FIG. 9 is an enlarged cross-sectional view of relevant portions showing one step of a method for manufacturing the semiconductor device according to the first embodiment of the present disclosure.

FIG. 10 is a cross-sectional view showing a first variation of the semiconductor device according to the first embodiment of the preset disclosure.

FIG. 11 is a plan view showing relevant portions of a second variation of the semiconductor device according to the first embodiment of the present disclosure.

FIG. 12 is a plan view showing relevant portions of a third variation of the semiconductor device according to the first embodiment of the present disclosure.

FIG. 13 is an enlarged cross-sectional view showing relevant portions of the semiconductor device according to a second embodiment of the present disclosure.

FIG. 14 is a plan view showing relevant portions of a semiconductor device according to a third embodiment of the present disclosure.

FIG. 15 is a plan view showing relevant portions of the semiconductor device according to the third embodiment of the present disclosure.

### DETAILED DESCRIPTION OF EMBODIMENTS

Hereinafter, preferred embodiments of the present disclosure will be specifically described with reference to the drawings.

The terms “first”, “second”, “third”, and the like in the present disclosure are used merely for identification, and are not intended to order these subjects.

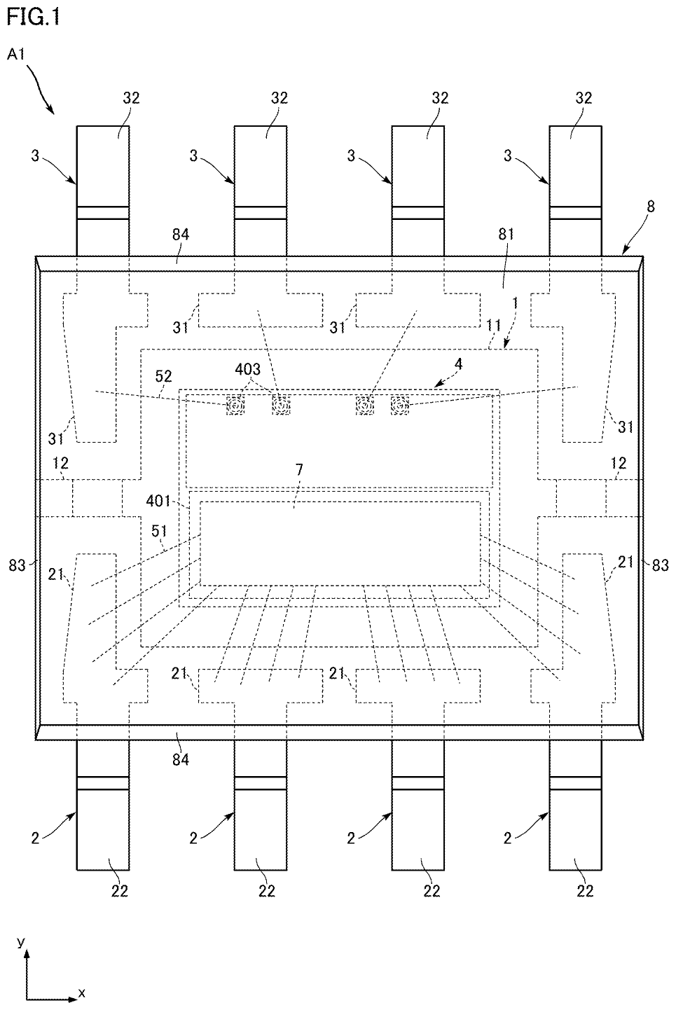

FIGS. 1 to 8 show a semiconductor device A1 according to a first embodiment of the present disclosure. The semiconductor device A1 of this embodiment includes a first lead 1, a plurality of second leads 2, a plurality of third leads 3, a semiconductor element 4, a plurality of first wires 51, a plurality of second wires 52, a covering portion 7, and a sealing resin 8. There is no particular limitation on the shape and the size of the semiconductor device A1. An example of the size of the semiconductor device A1 is as follows: the dimension in x direction is about 4 mm to 7 mm, the dimension in y direction is about 4 mm to 8 mm, and the dimension in z direction is about 0.7 mm to 2.0 mm.

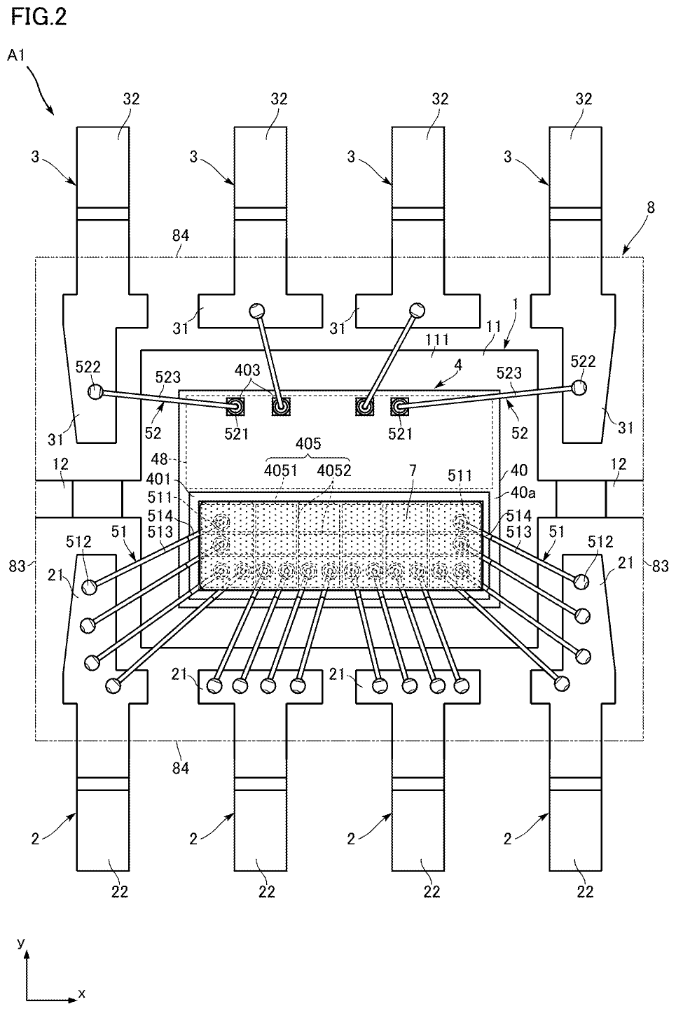

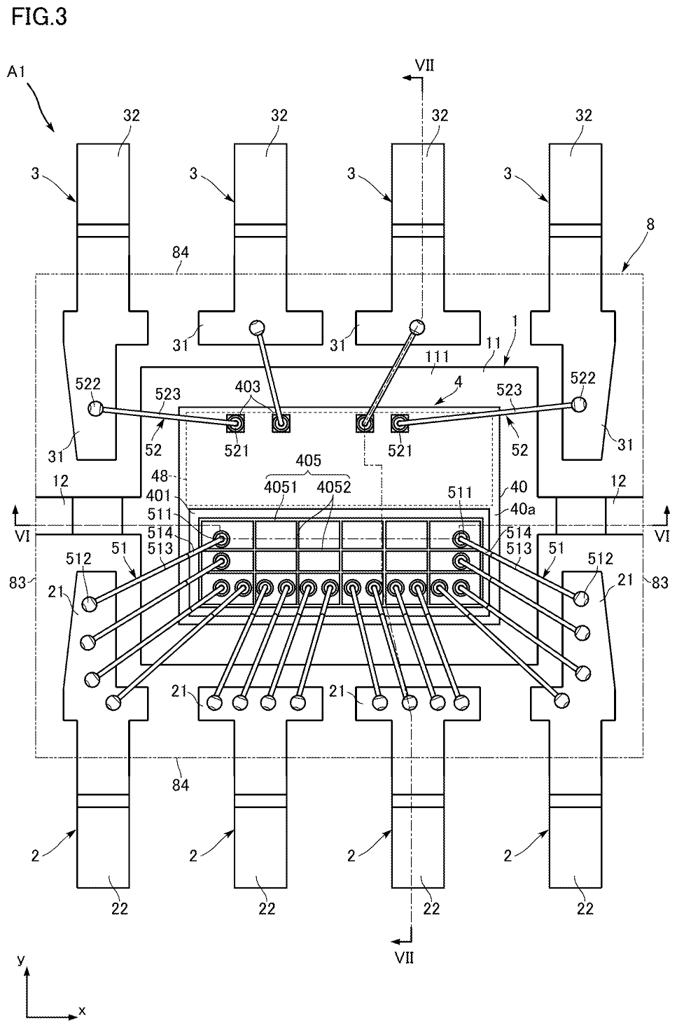

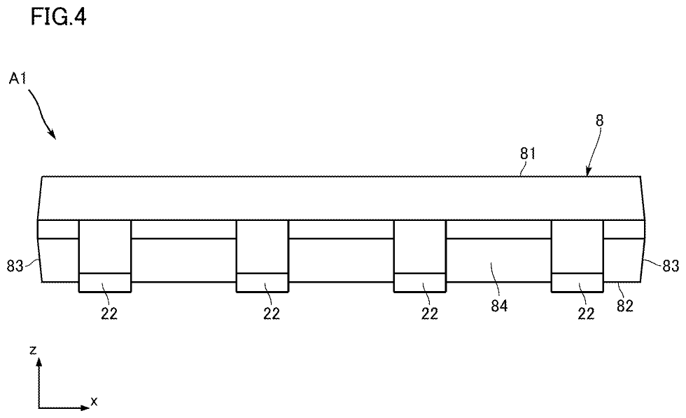

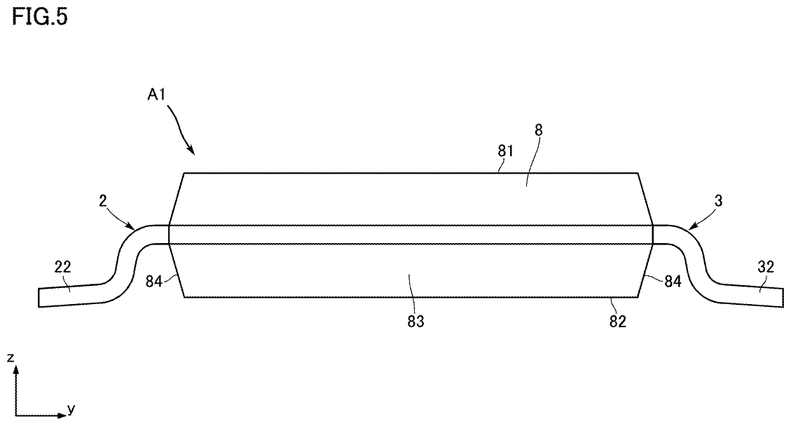

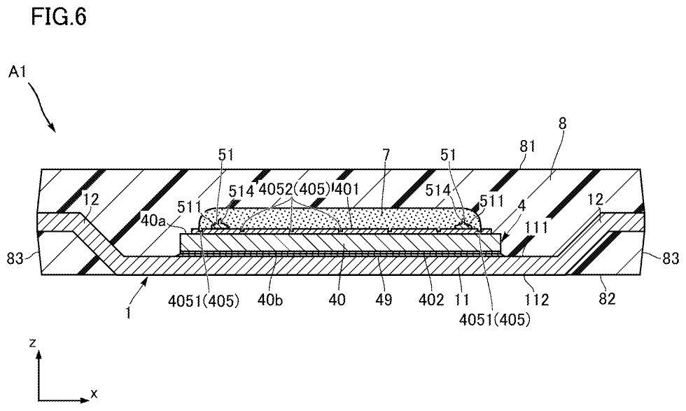

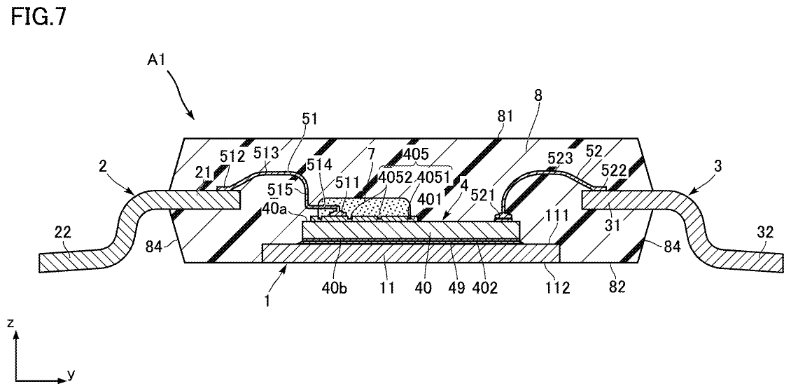

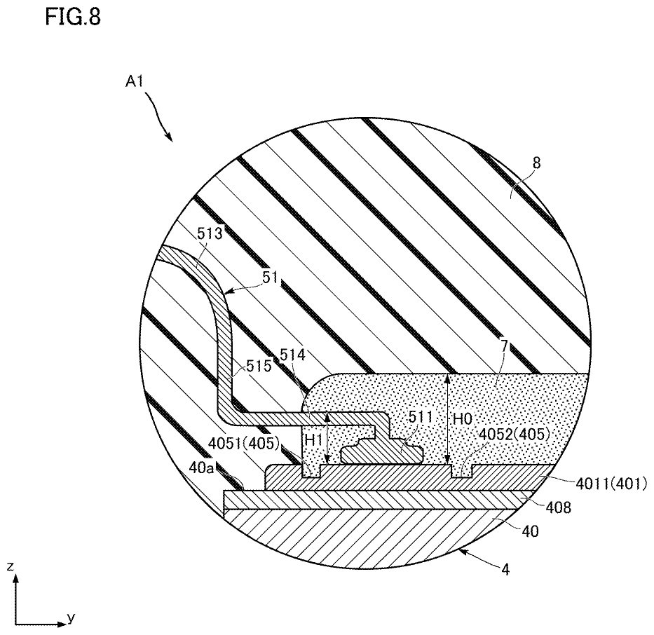

FIG. 1 is a plan view showing the semiconductor device A1. FIGS. 2 and 3 are plan views showing relevant portions of the semiconductor device A1. FIG. 4 is a front view showing the semiconductor device A1. FIG. 5 is a side view showing the semiconductor device A1. FIG. 6 is a cross-sectional view taken along line VI-VI in FIG. 3. FIG. 7 is a cross-sectional view taken along line VII-VII in FIG. 3. FIG. 8 is an enlarged cross-sectional view showing relevant portions of the semiconductor device A1. Note that the sealing resin 8 is indicated by an imaginary line in FIGS. 2 and 3 for the sake of convenience in understanding, the covering portion 7 is hatched with a plurality of dots in FIG. 2, and the covering portion 7 is omitted in FIG. 3 for the sake of convenience in understanding.

The first lead 1 is a member that supports the semiconductor element 4 and forms an electrical communication path to the semiconductor element 4. The material of the first lead 1 is not particularly limited, and the first lead 1 is made of, for example, a metal such as Cu (copper), Ni (nickel), or Fe (iron), or an alloy containing these metals. The first lead 1 may be provided with a plating layer made of a metal such as Ag (silver), Ni, Pd (palladium), or Au (gold) on an appropriate portion. The thickness of the first lead 1 is not particularly limited, and is, for example, about 0.12 mm to 0.2 mm.

The first lead 1 of this embodiment includes a die pad portion 11 and two extending portions 12.

The die pad portion 11 is a portion that supports the semiconductor element 4. The shape of the die pad portion 11 is not particularly limited, and is a rectangular shape as viewed in the z direction in this embodiment. The die pad portion 11 includes a die pad obverse surface 111 and a die pad reverse surface 112. The die pad obverse surface 111 faces in the z direction. The die pad reverse surface 112 faces a side opposite to the side that the die pad obverse surface 111 faces, in the thickness direction. In the example shown in the figures, the die pad obverse surface 111 and the die pad reverse surface 112 are flat.

The two extending portions 12 are portions that extend from the die pad portion 11 toward mutually opposite sides in the x direction. In this embodiment, each of the extending portions 12 includes a portion that extends from the die pad portion 11 in the x direction, a portion that is inclined with respect to the z direction and extends from that portion toward the side that the die pad obverse surface 111 faces, and a portion that extends from that portion in the direction, and has a bent shape as a whole (see FIG. 6).

The plurality of second leads 2 are portions that are spaced apart from the first lead 1 and form electrical communication paths to the semiconductor element 4. In this embodiment, the plurality of second leads 2 form electrical communication paths for an electric current switched by the semiconductor element 4. The plurality of second leads 2 are disposed on one side in the y direction with respect to the first lead 1. The plurality of second leads 2 are spaced apart from each other in the x direction.

The material of the second leads 2 is not particularly limited, and the second leads 2 are made of, for example, a metal such as Cu, Ni, or Fe, or an alloy containing these metals. Each of the second leads 2 may be provided with a plating layer made of a metal such as Ag, Ni, Pd, or Au on an appropriate portion. The thickness of the second leads 2 is not particularly limited, and is, for example, about 0.12 mm to 0.2 mm.

Each of the second leads 2 of this embodiment includes a pad portion 21 and a terminal portion 22.

The pad portion 21 is a portion to which the first wire 51 is connected. In this embodiment, the pad portion 21 is located on the side that the die pad obverse surface 111 faces with respect to the die pad portion 11 in the z direction (see FIG. 7).

The terminal portion 22 is a strip-shaped portion that extends outward in the y direction from the pad portion 21. The terminal portion 22 has a bent shape as viewed in the x direction, and the leading-end or front portion thereof is located at the same (or substantially the same) position as that of the die pad portion 11 in the z direction.

The plurality of third leads 3 are portions that are spaced apart from the first lead 1 and form electrical communication paths to the semiconductor element 4. In this embodiment, the plurality of third leads 3 form electrical communication paths for a control signal current for controlling the semiconductor element 4. The plurality of third leads 3 are disposed on the other side in the y direction with respect to the first lead 1. The plurality of third leads 3 are spaced apart from each other in the x direction.

The material of the third leads 3 is not particularly limited, and the third leads 3 are made of, for example, a metal such as Cu, Ni, or Fe, or an alloy containing these metals. Each of the third leads 3 may be provided with a plating layer made of a metal such as Ag, Ni, Pd, or Au on an appropriate portion. The thickness of the third leads 3 is not particularly limited, and is, for example, about 0.12 mm to 0.2 mm.

Each of the third leads 3 of this embodiment includes a pad portion 31 and a terminal portion 32.

The pad portion 31 is a portion to which a second wire 52 is connected. In this embodiment, the pad portion 31 is located on the side that the die pad obverse surface 111 faces with respect to the die pad portion 11 in the z direction (see FIG. 7).

The terminal portion 32 is a strip-shaped portion that extends outward in the y direction from the pad portion 31. The terminal portion 32 has a bent shape as viewed in the x direction, and the leading-end portion thereof is located at the same (or substantially the same) position as that of the die pad portion 11 in the z direction.

The semiconductor element 4 is an element that exerts an electrical function of the semiconductor device A1. In this embodiment, the semiconductor element 4 performs a switching function. The semiconductor element 4 includes an element body 40, a first electrode 401, a second electrode 402, and a plurality of third electrodes 403. The semiconductor element 4 further includes a control unit 48. With this configuration, the semiconductor element 4 includes a portion that forms a transistor that performs a switching function, and a portion that performs control, monitoring, protection, and the like of the transistor.

There is no particular limitation on the specific configuration of the semiconductor element 4. For example, a configuration may also be employed in which the semiconductor element 4 includes a functional layer 408 serving as the portion that forms a transistor, and the like, and does not include the control unit 48. In this case, the number of the second electrode 402 and the third electrodes 403 are selected as appropriate, or the second electrode 402 and the third electrodes 403 may be omitted. Also, only the semiconductor element 4 may be installed on the die pad portion 11, or another semiconductor element in addition to the semiconductor element 4 may be installed on the die pad portion 11. There is no particular limitation on the function exerted by the semiconductor element other than the semiconductor element 4.

The element body 40 includes an element obverse surface 40a and an element reverse surface 40b. The element obverse surface 40a faces the same side as the side that the die pad obverse surface 111 faces, in the z direction. The element reverse surface 40b faces a side opposite to the side that the element obverse surface 40a faces, in the z direction. There is no particular limitation on the material of the element body 40. Examples of the material of the element body 40 include semiconductor materials such as Si, SiC, and GaN.

For example, as shown in FIG. 8, the element body 40 includes a functional layer 408. For example, a transistor structure such as a MOSFET (Metal Oxide Semiconductor Field Effect Transistor) or a MISFET (Metal Insulator Semiconductor Field Effect Transistor) is built in the functional layer 408. The functional layer 408 is lined up with the control unit 48 in the y direction as viewed in the z direction. However, there is no particular limitation on the specific arrangement of the functional layer 408 and the control unit 48, and the like.

The first electrode 401 is disposed on the element obverse surface 40a of the element body 40. There is no particular limitation on the shape, the size, and the position of the first electrode 401. In the example shown in the figures, the first electrode 401 is disposed on a portion of the element obverse surface 40a near the plurality of second leads 2 in the y direction. The first electrode 401 overlaps with the functional layer 408 as viewed in the z direction. In this embodiment, the first electrode 401 is spaced apart from the control unit 48 as viewed in the z direction. In this embodiment, the first electrode 401 is a source electrode. The material of the first electrode 401 is not particularly limited, and examples thereof include metals such as Al (aluminum), Al—Si (silicon), and Cu, and alloys containing these metals. The first electrode 401 may have a structure in which layers made of a plurality of materials selected from these metals are stacked.

As shown in FIGS. 2, 3, and 6 to 8, the first electrode 401 of this embodiment includes a groove portion 405. The groove portion 405 is a portion that is recessed toward the semiconductor element 4 in the z direction. There is no particular limitation on the specific configuration of the groove portion 405.

In this embodiment, the first electrode 401 includes a first layer 4011. The first layer 4011 is a layer containing a metal such as Al, Al—Si, or Cu, an alloy containing these metals, or the like. The groove portion 405 is formed by recessing an appropriate portion of the first layer 4011 in the z direction. A method for forming such a groove portion 405 is not particularly limited, and etching, laser trimming, and the like can be used as appropriate, for example.

The groove portion 405 of this embodiment includes an outer peripheral portion 4051 and an inner portion 4052. The outer peripheral portion 4051 is a portion extending along the outer peripheral edge of the first electrode 401. The shape of the outer peripheral portion 4051 is not particularly limited, and is, for example, a rectangular shape. The outer peripheral portion 4051 may be constituted by a single line forming an annular shape, or be constituted by a dotted line containing a plurality of segments.

The inner portion 4052 is a portion located inside the outer peripheral portion 4051. The inner portion 4052 is linked to the outer peripheral portion 4051, but may be spaced apart from the outer peripheral portion 4051. There is no particular limitation on the shape and the size of the inner portion 4052. In the example shown in the figures, the inner portion 4052 has a lattice shape extending in the x direction and the y direction.

The second electrode 402 is disposed on the element reverse surface 40b of the element body 40. The second electrode 402 overlaps with the functional layer 408 and the control unit 48 as viewed in the z direction, and covers the entire element reverse surface 40b in this embodiment. In this embodiment, the second electrode 402 is a drain electrode. The material of the second electrode 402 is not particularly limited, and examples thereof include metals such as Al, Al—Si, and Cu, and alloys containing these metals. The second electrode 402 may have a structure in which layers made of a plurality of materials selected from these metals are stacked.

There is no particular limitation on the specific configuration of the control unit 48. The control unit 48 includes, for example, a current sensor circuit, a temperature sensor circuit, an overcurrent protection circuit, a heating protection circuit, an undervoltage lock-out circuit, and the like.

The plurality of third electrodes 403 are disposed on the element obverse surface 40a. In the example shown in the figures, the plurality of third electrodes 403 are disposed on a portion of the element obverse surface 40a near the plurality of third leads 3 in the y direction. The plurality of third electrodes 403 overlap with the control unit 48 as viewed in the z direction. In this embodiment, the plurality of third electrodes 403 are mainly in electrical communication with the control unit 48. There is no particular limitation on the number of the plurality of third electrodes 403. The number of the third electrodes 403 may be one. In the example shown in the figures, the semiconductor element 4 includes four third electrodes 403.

The plurality of first wires 51 enable electrical communication between the first electrode 401 of the semiconductor element 4 and the plurality of second leads 2. The material of the first wires 51 is not particularly limited, and the first wires 51 are made of, for example, a metal such as Au, Cu, or Al. As shown in FIGS. 2, 3, and 6 to 8, each of the first wires 51 of this embodiment includes a bonding portion 511, a bonding portion 512, a loop portion 513, a first portion 514, and a second portion 515. There is no particular limitation on the specific configuration of the first wire 51. In the example shown in the figures, the first wire 51 is made of a material containing Cu, and is formed using, for example, a capillary. In this embodiment, an electric current switched by the semiconductor element 4 flows through the plurality of first wires 51.

The semiconductor device according to the present disclosure is not limited to the configuration in which the first wire 51 is bonded to the first electrode 401. For example, it may have a configuration in which a conductive member made of a metal material, other than the first wire 51, is bonded to the first electrode 401. Alternatively, the semiconductor device may have a configuration in which an additional electrode is provided to electrically conduct to the first electrode 401 via a conductive path formed within the semiconductor element 4, and a given conductive member including e.g., the first wire 51 is electrically connected to the additional electrode.

The bonding portion 511 is in electrical communication with the first electrode 401 of the semiconductor element 4, and is disposed at a position that overlaps with the first electrode 401 as viewed in the z direction. In this embodiment, the bonding portion 511 is joined to the first electrode 401, and is also referred to as a first bonding portion.

There is no particular limitation on the arrangement of the bonding portion 511. In this embodiment, the bonding portion 511 is disposed at a position on the first electrode 401 that is not located on the groove portion 405. Also, the bonding portion 511 is disposed inside the outer peripheral portion 4051. Also, the bonding portions 511 of the plurality of first wires 51 are disposed in a dispersed manner in a plurality of regions on the first electrode 401 delimited by the groove portion 405.

The bonding portion 512 is a portion joined to the pad portion 21 of the second lead 2. The bonding portion 512 is also referred to as a second bonding portion.

The first portion 514 is a portion that extends from the inside of the first electrode 401 toward the outside of the first electrode 401 as viewed in the z direction. In the example shown in the figures, the first portion 514 is a portion that extends from the inside of the first electrode 401 to the outside of the first electrode 401 across the outer edge of the first electrode 401 as viewed in the z direction. The first portion 514 extends in parallel (or substantially parallel) with the xy plane.

The first portion 514 of this embodiment is integrally linked to the bonding portion 511. That is to say, the first portion 514 is formed so as to be continuous with the bonding portion 511 in the formation of the first wire 51.

The second portion 515 is linked to the first portion 514 on a side opposite to the first electrode 401 (bonding portion 511). The second portion 515 stands upright in the z direction on a side away from the semiconductor element 4 (i.e., on the upper side in the figure).

In this embodiment, the loop portion 513 is linked to the bonding portion 512 and the second portion 515, and has a curved shape.

In the example shown in the figures, the plurality of bonding portions 511 are disposed along the outer edge of the first electrode 401. More specifically, the bonding portions 511 are disposed along three sides included in the outer edge of the element body 40. Also, the bonding portions 511 are lined up in a row along the outer edge of the first electrode 401.

The plurality of second wires 52 enable electrical communication between the third electrodes 403 of the semiconductor element 4 and the plurality of third leads 3. The material of the second wires 52 is not particularly limited, and the second wires 52 are made of, for example, a metal such as Au, Cu, or Al. Each of the second wires 52 includes a bonding portion 521, a bonding portion 522, and a loop portion 523. There is no particular limitation on the specific configuration of the second wire 52. In the example shown in the figures, the second wire 52 is formed using, for example, a capillary. In this embodiment, a control signal current for controlling the semiconductor element 4 flows through the plurality of second wires 52.

The bonding portion 521 is joined to the second electrode 402 of the semiconductor element 4. The bonding portion 521 is also referred to as a first bonding portion.

The bonding portion 522 is a portion joined to the pad portion 31 of the third lead 3. The bonding portion 522 is also referred to as a second bonding portion.

The loop portion 523 is linked to the bonding portion 521 and the bonding portion 522, and has a curved shape.

The covering portion 7 is interposed between the first electrode 401 and the sealing resin 8. The covering portion 7 contains a material having a higher thermal conductivity than the sealing resin 8. There is no particular limitation on the material of the covering portion 7, and in the case where the sealing resin 8 is made of an insulating resin, the covering portion 7 contains a metal. The covering portion 7 contains, for example, Ag or Cu as the metal. Also, the covering portion 7 contains sintered Ag or sintered Cu. For example, in the case where the covering portion 7 contains sintered Ag, it is preferable to use sintered Ag of a type capable of being formed without the application of pressure. In the case where the covering portion 7 is made of sintered Ag formed without the application of pressure, the covering portion 7 can be formed by, for example, ejecting a material paste for forming sintered Ag from a nozzle, applying the material paste, and then heating the material paste as appropriate.

The structure of the covering portion 7 is not limited to a metal-containing structure, and the covering portion 7 may contain, for example, a resin having a higher thermal conductivity than an insulating resin constituting the sealing resin 8. In the case where the sealing resin 8 is made of an epoxy resin, examples of the resin contained in the covering portion 7 include an epoxy resin, an acrylic resin, and the like to which a filler for improving the thermal conductivity is mixed. In the case where the sealing resin 8 contains a filler, examples of the resin contained in the covering portion 7 include resins in which the content of the filler is higher than the content of the filler in the sealing resin 8.

In this embodiment, the covering portion 7 contains sintered Ag, and is in contact with both the first electrode 401 and the sealing resin 8. The covering portion 7 is disposed inside the outer edge of the first electrode 401 as viewed in the z direction.

The covering portion 7 is in contact with the groove portion 405. The covering portion 7 is disposed on the outer peripheral portion 4051 of the groove portion 405, or inside the outer peripheral portion 4051 as viewed in the z direction. The covering portion 7 covers the inner portion 4052.

The covering portion 7 is in contact with the first portions 514 of the plurality of first wires 51. The covering portion 7 is in contact with the bonding portions 511. As shown in FIG. 8, in the example shown in the figure, a height H0 corresponding to the distance from the first electrode 401 to a portion of the covering portion 7 that is the farthest from the first electrode 401 is larger than a height H1 corresponding to the distance from the first electrode 401 to a portion of the first portion 514 that is the farthest from the first electrode 401, in the z direction. In the example shown in the figures, the covering portion 7 covers the bonding portions 511. The covering portion 7 covers at least partially the first portions 514 from the upper side in the z direction (i.e., from a side opposite to the semiconductor element 4). In other words, each of the first portions 514 protrudes from the covering portion 7 in a direction (the y direction in the example shown in the figures) orthogonal to the z direction.

The sealing resin 8 covers the first lead 1, portions of the plurality of second leads 2 and the plurality of third leads 3, the semiconductor element 4, the plurality of first wires 51, the plurality of the second wires 52, and the covering portion 7. The sealing resin 8 is made of an insulating resin, and an example thereof is an epoxy resin to which a filler is mixed.

There is no particular limitation on the shape of the sealing resin 8. In the example shown in the figures, the sealing resin 8 includes a resin obverse surface 81, a resin reverse surface 82, two first resin side surfaces 83, and two second resin side surfaces 84.

The resin obverse surface 81 faces the same side as the side that the die pad obverse surface 111 faces, in the z direction, and is flat, for example. The resin reverse surface 82 faces a side opposite to the side that the resin obverse surface 81 faces, in the z direction, and is flat, for example.

The two first resin side surfaces 83 are located between the resin obverse surface 81 and the resin reverse surface 82 in the z direction, and face mutually opposite sides in the x direction. The two second resin side surfaces 84 are located between the resin obverse surface 81 and the resin reverse surface 82 in the z direction, and face mutually opposite sides in the y direction.

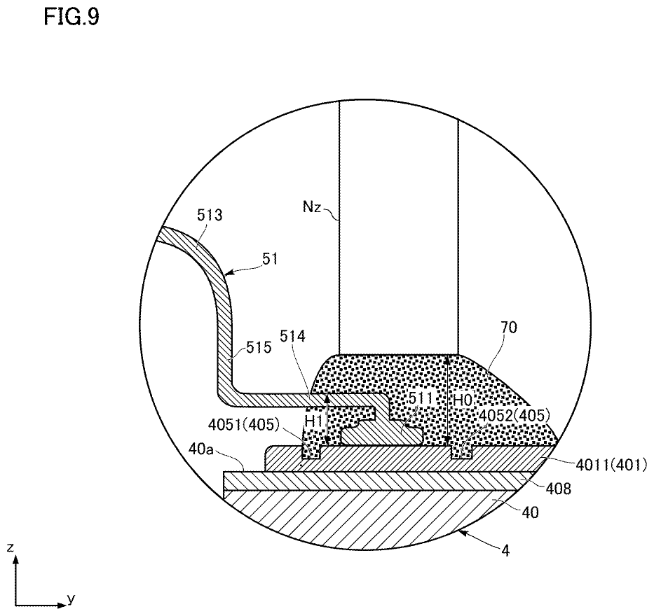

FIG. 9 shows one step of an example of a method for manufacturing the semiconductor device A1. In the step shown in the figure, a material paste 70 is applied to the first electrode 401 in order to form the covering portion 7. There is no particular limitation on the material paste 70. For example, in the case where the covering portion 7 contains sintered Ag, the material paste 70 is a Ag-containing paste. Thus, sintered Ag can be formed through pressureless sintering.

A nozzle Nz is moved along the xy plane while the material paste 70 is ejected from the leading end (lower end in the figure) of the nozzle Nz. At this time, a height H0 of the leading end of the nozzle Nz from the first electrode 401 is larger than a height H1 of the first portion 514. Accordingly, the nozzle Nz can be located right above the bonding portion 511 and the first portion 514. In the example shown in the figure, the height H0 is smaller than the height of a portion of the loop portion 513 that is the farthest from the first electrode 401 in the z direction.

Next, the effects of the semiconductor device A1 will be described.

The first electrode 401 includes the groove portion 405. The material paste 70 and the like for forming the covering portion 7 are likely to spread along the groove portion 405 due to surface tension. Thus, the covering portion 7 can be more reliably formed in the region in which the groove portion 405 is provided. During the operation of the semiconductor element 4, energy produced by an electromotive force generated due to an electric current being blocked is at least partially converted into heat. If this heat stays inside the semiconductor element 4, the temperature of the semiconductor element 4 will excessively rise. The covering portion 7 is interposed between the first electrode 401 and the sealing resin 8, and contains a material having a higher thermal conductivity than the sealing resin 8. Thus, heat transfer from the first electrode 401 to the covering portion 7 is promoted, thus making it possible to suppress an excessive rise in the temperature of the semiconductor element 4. Accordingly, with the semiconductor device A1, it is possible to increase energy that can be absorbed through active clamping.

The groove portion 405 includes the outer peripheral portion 4051. Providing the outer peripheral portion 4051 makes it possible to suppress a phenomenon in which the material paste 70 spreads into an unintended region on the first electrode 401 and leaks to the outside of the first electrode 401, and the like.

The groove portion 405 includes the inner portion 4052. Spreading the material paste 70 along the inner portion 4052 makes it possible to spread the material paste 70 in a desired region. Accordingly, it is possible to suppress formation of a structure in which the thickness of the covering portion 7 is partially increased to a significant extent, and make the thickness of the covering portion 7 more uniform.

Each of the first wires 51 includes the first portion 514. The first portion 514 extends from the inside of the first electrode 401 toward the outside thereof. The covering portion 7 is in contact with the first portion 514. That is to say, when the covering portion 7 is formed, the nozzle Nz for supplying the material paste 70 passes through the vicinity of the first portion 514. The first portion 514 extends in a direction intersecting the z direction, and the height H1 can be reduced. Thus, it is possible to suppress interference of the nozzle Nz with the first wire 51, and it is possible to form the covering portion 7 in a broader region. Accordingly, with the semiconductor device A1, it is possible to increase energy that can be absorbed through active clamping.

The height H0 of the covering portion 7 is larger than the height H1 of the first portion 514. Thus, a form in which the covering portion 7 is in contact with more portions can be achieved. For example, the covering portion 7 can protect the first portion 514. Meanwhile, the first portion 514 can suppress separation of the covering portion 7.

The covering portion 7 covers the first portions 514 from the upper side in the z direction (i.e., from a side opposite to the semiconductor element 4). Thus, the covering portion 7 can more reliably protect the first portion 514.

The first portion 514 is integrally linked to the bonding portion 511. Thus, a portion where the first portion 514 and the bonding portion 511 are linked together is likely to have a sharply curved shape. Covering this portion with the covering portion 7 makes it possible to further improve the effect of protecting the first wire 51.

The first wire 51 includes the second portion 515 linked to the first portion 514. Due to the second portion 515 being included, the first wire 51 has such a shape that steeply stands upright from the first portion 514 in the z direction. Thus, the loop portion 513 can be linked to the bonding portion 512 while the shape of the loop portion 513 is maintained in an appropriate loop shape.

The bonding portions 511 of the plurality of first wires 51 are disposed along the outer edge of the first electrode 401. Thus, it is possible to suppress hindrance to the application of the material paste 70 caused by the bonding portion 511.

In the case where the covering portion 7 contains a metal, heat transfer from the first electrode 401 can be further improved. In the case where Ag or Cu is selected as the metal contained in the covering portion 7, the thermal conductivity of the covering portion 7 can be further improved. In the case where the covering portion 7 contains sintered Ag or sintered Cu, the covering portion 7 having a desired shape can be more reliably formed by applying a material paste and sintering this material paste.

In the case where the covering portion 7 contains a metal, the covering portion 7 forms a conductive member that is in contact with the first electrode 401. Thus, an electrical communication path from a certain portion of the functional layer 408 to any of the first wires 51 can be formed by the first electrode 401 as well as the covering portion 7. Accordingly, the resistance of the semiconductor element 4 can be reduced.

A heat transfer path through which heat can be mutually transferred between the covering portion 7 and the first wire 51 is formed due to contact of the covering portion 7 with the bonding portion 511 of the first wire 51. Accordingly, it is possible to, for example, dissipate heat transferred to the covering portion 7 to the second lead 2 via the first wire 51.

In the case where the first electrode 401 contains Al and the covering portion 7 contains sintered Ag, the joining strength between the first electrode 401 and the covering portion 7 may be insufficient. However, in the case where the first wire 51 contains Cu, both the joining strength between the first electrode 401 and the first wire 51 and the joining strength between the first wire 51 and the covering portion 7 are higher than the joining strength between the first electrode 401 and the covering portion 7. Thus, it is possible to suppress separation of the covering portion 7 from the first electrode 401, etc.

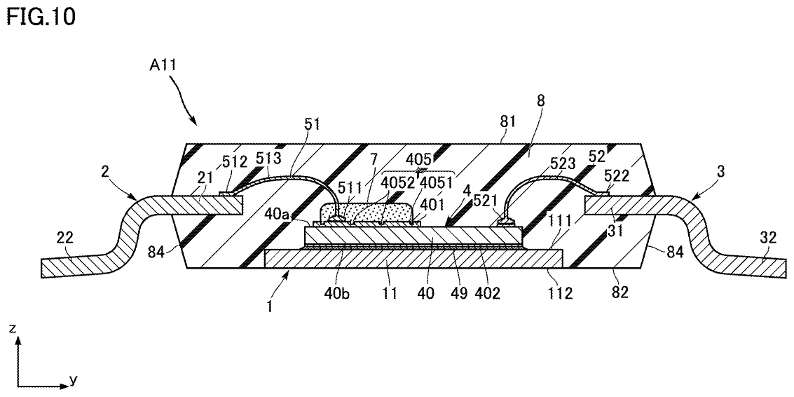

FIGS. 10 to 15 show variations and other embodiments of the present disclosure. Note that, in these figures, components that are identical or similar to those of the above-described embodiment are given the same reference numerals as those in the above-described embodiment. Moreover, the configurations of the portions of the variations and the embodiments can be used in combination.

FIG. 10 is a cross-sectional view of a first variation of the semiconductor device A1. The semiconductor device All in this variation has a different configuration regarding the first wire 51 than the first wire 51 of the semiconductor device A1 described above.

The first wire 51 of this embodiment does not have the first portion 514 and the second portion 515 described above. Further, the loop portion 513 is connected to the bonding portion 511 and the bonding portion 512. In the figure, the loop portion 513 protrudes from the covering portion 7 upwardly in the z-direction.

With the illustrated arrangements, it is possible to increase energy that can be absorbed through active clamping. As seen from such a variation, the configurations of the first wire 51 are not particularly limited.

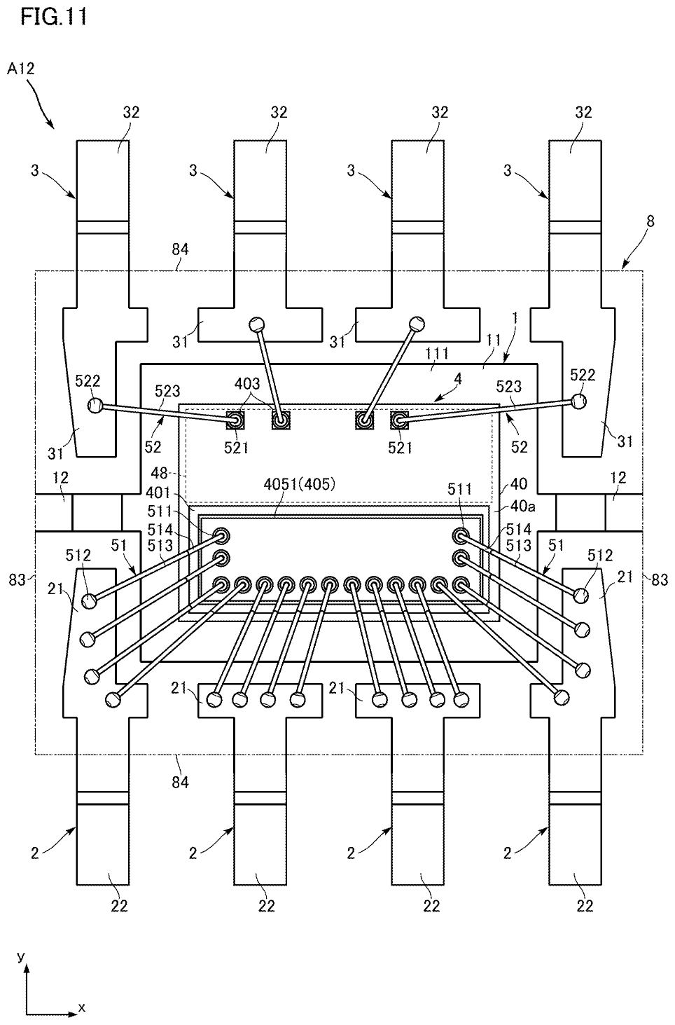

FIG. 11 is a plan view showing relevant portions of a second variation of the semiconductor device A1. In this figure, for convenience of understanding, the covering portion 7 is omitted. The semiconductor device A12 in this variation differs from the semiconductor device A1 described above in the configuration of the groove portion 405.

The groove portion 405 of this variation includes an outer peripheral portion 4051 and does not have an inner portion 4052. The area of the first electrode 401 surrounded by the outer peripheral portion 4051 is flat. In this variation, the covering portion 7 may be in contact with the outer peripheral portion 4051 of the groove portion 405 or may be positioned inwardly from the outer peripheral portion 4051 as viewed in the z-direction.

With the illustrated arrangements, it is possible to increase energy that can be absorbed through active clamping. As seen from such a variation, the configurations of the groove portion 405 are not particularly limited.

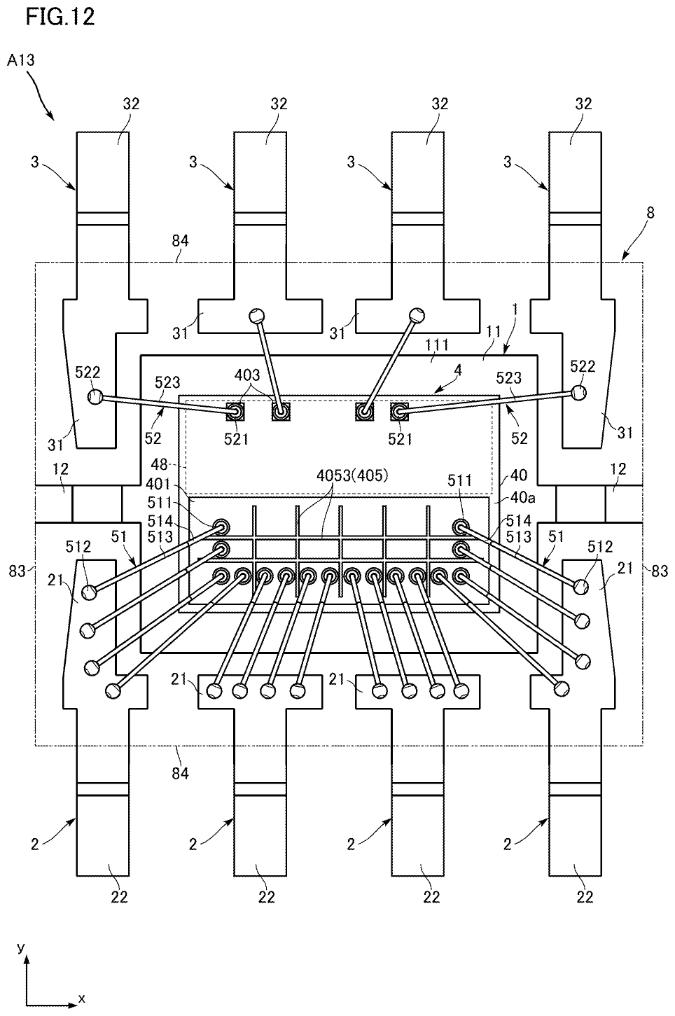

FIG. 12 is a plan view showing relevant portions of a third variation of the semiconductor device A1. In this figure, for convenience of understanding, the covering portion 7 is omitted. The semiconductor device A13 in this variation has different configurations regarding the groove portion 405.

The groove portion 405 in this variation has a lattice portion 4053 and does not have the outer peripheral portion 4051 described above. The lattice portion 4053 includes grooves extending in the x- and y-directions, which has the same pattern as the inner portion 4052 described above. In this variation, the lattice portion 4053 is covered by the covering portion 7.

With the illustrated arrangements, it is possible to increase energy that can be absorbed through active clamping. As seen from such a variation, the configurations of the groove portion 405 are not particularly limited.

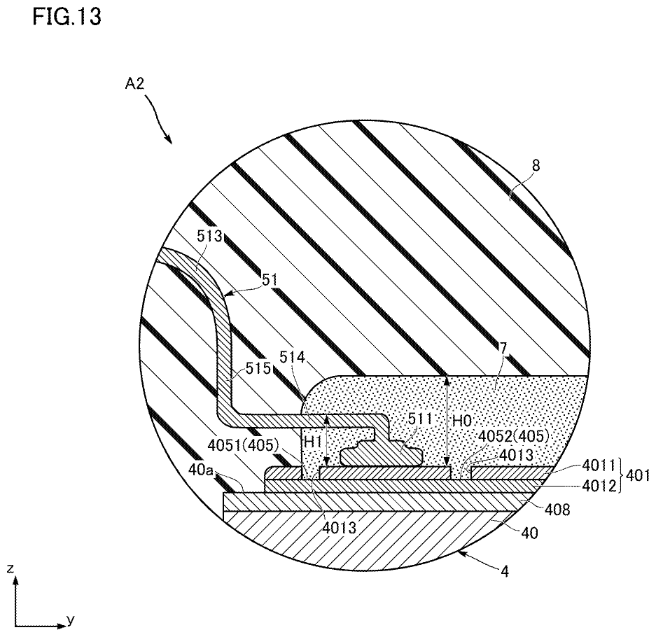

FIG. 13 is an enlarged cross-sectional view showing relevant portions of a semiconductor device according to a second embodiment of the present disclosure. The semiconductor device A2 of this embodiment may have different configurations regarding the first electrode 401.

The first electrode 401 of this embodiment includes a first layer 4011 and a second layer 4012.

The second layer 4012 is disposed between the element body 40 (element obverse surface 40a) and the first layer 4011. The second layer 4012 is in contact with the first layer 4011. Alternatively, there may be another layer or layers disposed between the second layer 4012 and the element body 40 (element obverse surface 40a). The second layer 4012 may be a layer containing a metal such as Al, Al—Si and Cu, for example, or a metal alloy containing such a metal.

The first layer 4011 is stacked on the second layer 4012. The first layer 4011 may be formed with slits 4013. The slits 4013 extend throughout the first layer 4011 in the z direction. In this embodiment, the slits 4013 and the parts of the second layer 4012 that overlap with the slits 4013 as viewed in the z direction provide the groove portion 405.

With the illustrated arrangements, it is possible to increase energy that can be absorbed through active clamping. As seen from such a variation, the configurations of the groove portion 405 are not particularly limited.

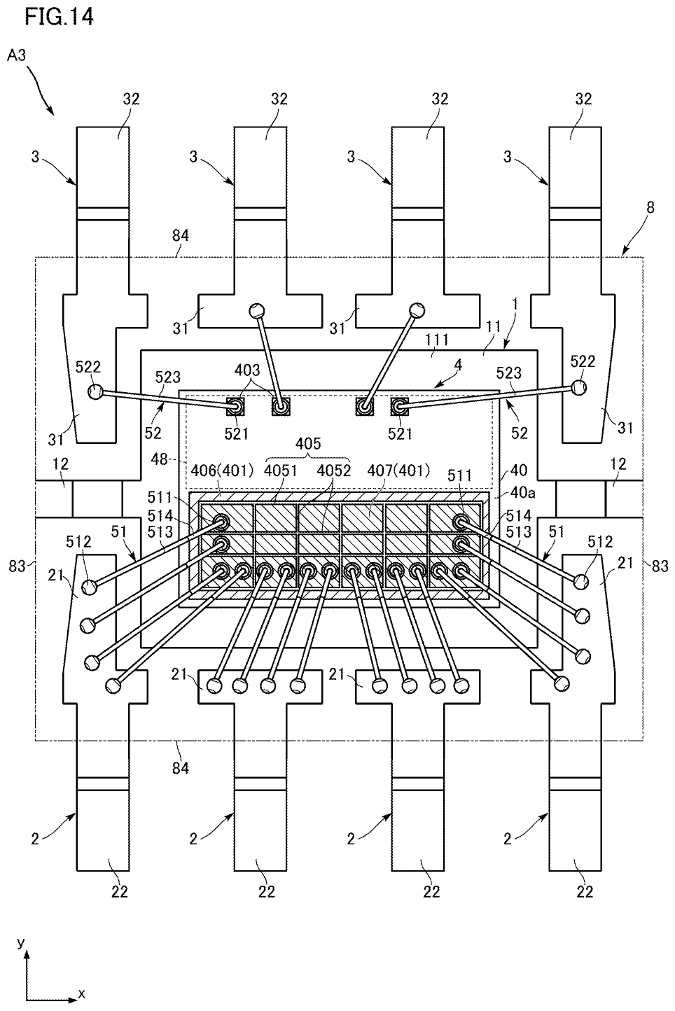

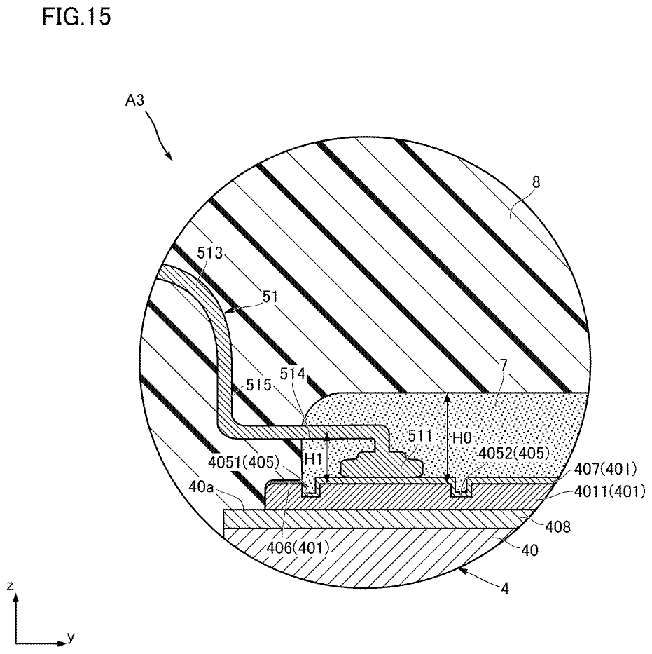

FIGS. 14 and 15 are a plan view and an enlarged cross-sectional view showing relevant portions of a semiconductor device according to a third embodiment of the present disclosure. In FIG. 14, for convenience of understanding, the covering portion 7 is omitted. The semiconductor device A3 in this embodiment may have different configurations regarding the first electrode 401.

The first electrode 401 of this embodiment includes a first layer 4011, an oxide layer 406 and a plating layer 407. The oxide layer 406 is a layer produced by oxidization of the metal contained in a surface of the first layer 4011. The oxide layer 406 is disposed outward of the outer peripheral portion 4051 of the groove portion 405 as viewed in the z direction. The oxide layer 406 has lower wettability, than the first layer 4011, to the material paste 70 for forming the covering portion 7 that contains sintered Ag.

The plating layer 407 is a layer produced by plating on the first layer 4011. The plating layer 407 contains a component that has higher wettability, than the first layer 4011, to the material paste 70 for forming the covering portion 7 that contains sintered Ag. For instance, when the first layer 4011 contains Cu, the plating layer 407 may contain Ni, Pd, and Au, for example. The plating layer 407 is disposed inward of the outer peripheral portion 4051 as viewed in the z direction. The plating layer 407 may be disposed to cover the inner portion 4052 or to avoid covering the inner portion 4052.

With the illustrated arrangements, it is possible to increase energy that can be absorbed through active clamping. Further, the provision of the oxide layer 406 is capable of preventing the material paste 70 for forming the covering portion 7 from unduly spreading outward beyond the outer peripheral portion 4051. In addition, the provision of the plating layer 407 serves to cause the material paste 70 for forming the covering portion 7 to spread widely over the region within the outer peripheral portion 4051.

The semiconductor device according to the present disclosure is not limited to the above-described embodiments. Various modifications in design may be made freely in the specific structure of each part of the semiconductor device according to the present disclosure. The present disclosure includes embodiments described in the following clauses.

Clause 1.

A semiconductor device including:

a semiconductor element that includes an element body containing a semiconductor and a first electrode disposed on the element body;

a sealing resin that covers the semiconductor element; and

a covering portion interposed between the first electrode and the sealing resin, the covering portion containing a material having a higher thermal conductivity than the sealing resin,

wherein the first electrode includes a groove portion held in contact with the covering portion.

Clause 2.

The semiconductor device according to Clause 1, wherein the first electrode includes a first layer, and

the groove portion is a portion recessed in the first layer.

Clause 3.

The semiconductor device according to Clause 1, wherein the first electrode includes a first layer and a second layer disposed between the element body and the first layer, the second layer held in contact with the first layer, and

the groove portion is provided by a slit formed in the first layer and a portion of the second layer that is exposed through the slit.

Clause 4.

The semiconductor device according to any one of Clauses 1 to 3, wherein the groove portion includes an outer peripheral portion arranged along an outer circumference of the first electrode.

Clause 5.

The semiconductor device according to Clause 4, wherein the groove portion includes an inner portion disposed inward of the outer peripheral portion.

Clause 6.

The semiconductor device according to Clause 5, wherein the inner portion is lattice-shaped.

Clause 7.

The semiconductor device according to any one of Clauses 4 to 6, wherein the first electrode includes an oxide layer disposed outward of the outer peripheral portion.

Clause 8.

The semiconductor device according to any one of Clauses 4 to 7, wherein the first electrode includes a plating layer disposed inward of the outer peripheral portion.

Clause 9.

The semiconductor device according to any one of Clauses 1 to 8, wherein the covering portion contains a metal.

Clause 10.

The semiconductor device according to Clause 9, wherein the covering portion contains Ag or Cu.

Clause 11.

The semiconductor device according to Clause 10, wherein the covering portion contains sintered Ag or sintered Cu.

Clause 12.

The semiconductor device according to any one of Clauses 9 to 11, wherein the first wire contains Al.

Clause 13.

The semiconductor device according to any one of Clauses 1 to 12, further comprising a first wire bonded to the first electrode, wherein the first electrode includes a first portion extending from an inner part of the first electrode toward an outer part of the first electrode as viewed in a thickness direction of the semiconductor element, and

the covering portion is in contact with the first portion of the first wire.

Clause 14.

The semiconductor device according to Clause 13, wherein a distance from the first electrode to a portion of the covering portion that is the farthest from the first electrode is larger than a distance from the first electrode to a portion of the first portion that is the farthest from the first electrode.

Clause 15.

The semiconductor device according to Clause 14, wherein the covering portion covers at least a part of the first portion from a location opposite to the semiconductor element in the thickness direction.

Clause 16.

The semiconductor device according to any one of Clauses 13 to 15, wherein the first wire includes a second portion connected to the first portion at a side opposite to the first electrode, the second portion being upright along the thickness direction and extending away from the semiconductor element.

Clause 17.

The semiconductor device according to any one of Clauses 13 to 16, wherein the first wire contains Cu.

### REFERENCE NUMERALS

A1, A11, A12, A13, A2, A3: Semiconductor device
1: First lead 2: Second lead 3: Third lead
4: Semiconductor element 7: Covering portion
8: Sealing resin
11: Die pad portion 12: Extending portion
21: Pad portion
22: Terminal portion 31: Pad portion
32: Terminal portion
40: Element body 40a: Element obverse surface
40b: Element reverse surface
48: Control unit 51: First wire 52: Second wire
70: Material paste 81: Resin obverse surface
82: Resin reverse surface
83: First resin side surface 84: Second resin side surface
111: Die pad obverse surface 112: Die pad reverse surface
401: First electrode 402: Second electrode
403: Third electrode
405: Groove portion 406: Oxide layer 407: Plating layer
408: Functional layer 511, 512: Bonding portion
513: Loop portion 514: First portion 515: Second portion
521, 522: Bonding portion 523: Loop portion
4011: First layer 4012: Second layer
4013: Slit 4051: Outer peripheral portion
4052: Inner portion 4053: Lattice portion
H0, H1: Height Nz: Nozzle

1. A semiconductor device including:
a semiconductor element that includes an element body containing a semiconductor and a first electrode disposed on the element body;
a sealing resin that covers the semiconductor element; and
a covering portion interposed between the first electrode and the sealing resin, the covering portion containing a material having a higher thermal conductivity than the sealing resin,
wherein the first electrode includes a groove portion held in contact with the covering portion.

2. The semiconductor device according to claim 1, wherein the first electrode includes a first layer, and
the groove portion is a portion recessed in the first layer.

3. The semiconductor device according to claim 1, wherein the first electrode includes a first layer and a second layer disposed between the element body and the first layer, the second layer held in contact with the first layer, and
the groove portion is provided by a slit formed in the first layer and a portion of the second layer that is exposed through the slit.

4. The semiconductor device according to claim 1, wherein the groove portion includes an outer peripheral portion arranged along an outer circumference of the first electrode.

5. The semiconductor device according to claim 4, wherein the groove portion includes an inner portion disposed inward of the outer peripheral portion.

6. The semiconductor device according to claim 5, wherein the inner portion is lattice-shaped.

7. The semiconductor device according to claim 4, wherein the first electrode includes an oxide layer disposed outward of the outer peripheral portion.

8. The semiconductor device according to claim 4, wherein the first electrode includes a plating layer disposed inward of the outer peripheral portion.

9. The semiconductor device according to claim 1, wherein the covering portion contains a metal.

10. The semiconductor device according to claim 9, wherein the covering portion contains Ag or Cu.

11. The semiconductor device according to claim 10, wherein the covering portion contains sintered Ag or sintered Cu.

12. The semiconductor device according to claim 9, wherein the first wire contains Al.

13. The semiconductor device according to claim 1, further comprising a first wire bonded to the first electrode,
wherein the first electrode includes a first portion extending from an inner part of the first electrode toward an outer part of the first electrode as viewed in a thickness direction of the semiconductor element, and
the covering portion is in contact with the first portion of the first wire.

14. The semiconductor device according to claim 13, wherein a distance from the first electrode to a portion of the covering portion that is the farthest from the first electrode is larger than a distance from the first electrode to a portion of the first portion that is the farthest from the first electrode.

15. The semiconductor device according to claim 14, wherein the covering portion covers at least a part of the first portion from a location opposite to the semiconductor element in the thickness direction.

16. The semiconductor device according to claim 13, wherein the first wire includes a second portion connected to the first portion at a side opposite to the first electrode, the second portion being upright along the thickness direction and extending away from the semiconductor element.

17. The semiconductor device according to claim 13, wherein the first wire contains Cu.
